(19) United States
(12) Patent Application Publication
(10) Pub. No.: US 2026/0031764 A1
(43) Pub. Date: Jan. 29, 2026

(54) ARCHITECTURE FOR DOHERTY POWER AMPLIFIER OUTPUT POWER COMBINING

(71) Applicant: QUALCOMM Incorporated, San Diego, CA (US)

(72) Inventors: Jun ZHAO, San Ramon, CA (US); Maksym RYBALKO, München (DE)

(21) Appl. No.: 18/784,602

(22) Filed: Jul. 25, 2024

(51) Int. Cl. H03F 1/02; H03F 1/56; H03F 3/24; H03F 3/60

(52) U.S. Cl. CPC H03F 1/0288; H03F 1/565; H03F 3/245; H03F 3/602; H03F 2200/294; H03F 2200/451

(57) ABSTRACT

A Doherty power amplifier (PA) includes a main amplifier, an auxiliary amplifier, a first inductor coupled between an output of the main amplifier and a first node, a second inductor coupled between an output of the auxiliary amplifier and the first node, and a third inductor coupled between a supply rail and the first node. The Doherty PA also includes a first capacitor coupled between the output of the main amplifier and a ground, a second capacitor coupled between the output of the auxiliary amplifier and the ground, and an impedance matching circuit coupled between the output of the auxiliary amplifier and an output of the Doherty PA.

### BACKGROUND

### Field

Aspects of the present disclosure relate generally to wireless communications, and, more particularly, to power amplifiers.

### Background

A wireless device includes a transmitter for transmitting radio frequency (RF) signals via one or more antennas. The transmitter may include power amplifiers for amplifying the RF signals before transmission. One or more of the power amplifiers may be implemented with a Doherty power amplifier, which includes a main amplifier and an auxiliary amplifier.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a Doherty power amplifier (PA). The Doherty PA includes a main amplifier, an auxiliary amplifier, a first inductor coupled between an output of the main amplifier and a first node, a second inductor coupled between an output of the auxiliary amplifier and the first node, and a third inductor coupled between a supply rail and the first node. The Doherty PA also includes a first capacitor coupled between the output of the main amplifier and a ground, a second capacitor coupled between the output of the auxiliary amplifier and the ground, and an impedance matching circuit coupled between the output of the auxiliary amplifier and an output of the Doherty PA.

A second relates to a system for wireless communications. The system includes a Doherty power amplifier (PA). The Doherty PA includes a main amplifier, an auxiliary amplifier, a first inductor coupled between an output of the main amplifier and a first node, a second inductor coupled between an output of the auxiliary amplifier and the first node, and a third inductor coupled between a supply rail and the first node. The system also includes a first capacitor coupled between the output of the main amplifier and a ground, a second capacitor coupled between the output of the auxiliary amplifier and the ground, and an impedance matching circuit coupled between the output of the auxiliary amplifier and an output of the Doherty PA. The system also includes an antenna coupled to the output of the Doherty PA.

### BRIEF DESCRIPTION OF THE DRAWINGS

FIG. 1 shows an example of a Doherty power amplifier including a main amplifier and an auxiliary amplifier according to certain aspects of the present disclosure.

FIG. 2A shows an example of the Doherty power amplifier of FIG. 1 in which the main amplifier includes a first bipolar junction transistor (BJT) and the auxiliary amplifier includes a second BJT according to certain aspects of the present disclosure.

FIG. 2B shows an example of the Doherty power amplifier of FIG. 1 in which the main amplifier includes a first field effect transistor (FET) and the auxiliary amplifier includes a second FET according to certain aspects of the present disclosure.

FIG. 3 shows an exemplary implementation of an output circuit of the Doherty power amplifier according to certain aspects of the present disclosure.

FIG. 4 shows an exemplary implementation of an impedance matching circuit according to certain aspects of the present disclosure.

FIG. 5 shows an example in which an output circuit of the Doherty power amplifier includes inductors coupled in a star network according to certain aspects of the present disclosure.

FIG. 6 shows an example in which the output circuit of FIG. 5 includes the exemplary impedance matching network of FIG. 4 according to certain aspects of the present disclosure.

FIG. 7A shows an exemplary layout of inductors according to certain aspects of the present disclosure.

FIG. 7B shows the exemplary layout of FIG. 7A with some of the layers of FIG. 7A omitted according to certain aspects of the present disclosure.

FIG. 8A shows an example of a Doherty power amplifier coupled to an antenna according to certain aspects of the present disclosure.

FIG. 8B shows an example of the antenna of FIG. 8A also coupled to a low-noise amplifier according to certain aspects of the present disclosure.

FIG. 9 is a diagram of an environment including an electronic device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

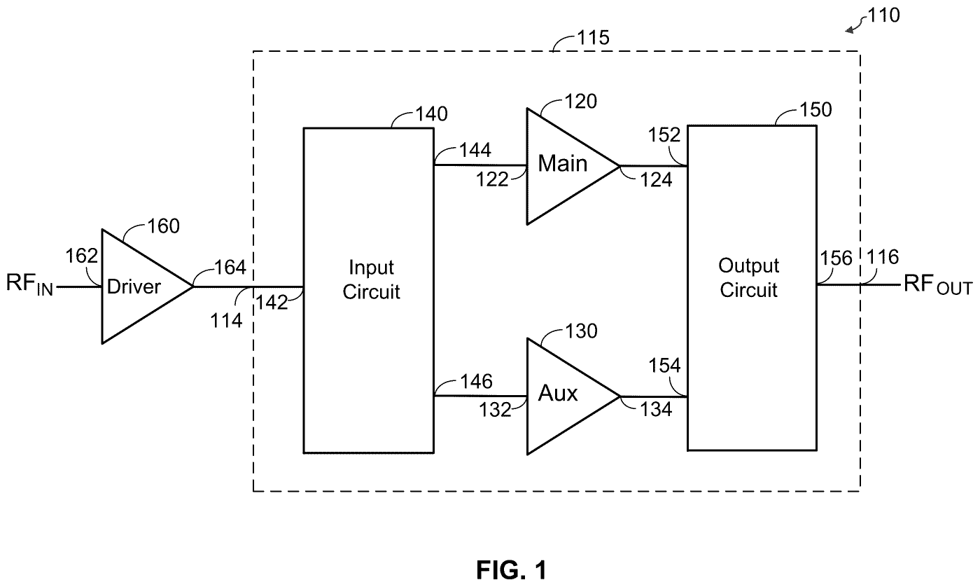

FIG. 1 shows an example of a system 110 including a driver 160 (also referred to as a drive stage) and a Doherty power amplifier (PA) 115 according to certain aspects. The system 110 may be included in a wireless device (e.g., a mobile device or a base station) for amplifying an RF signal before transmission via one or more antennas.

In the example in FIG. 1, the driver 160 has an input 162 and an output 164, and the Doherty PA 115 has an input 114 and an output 116. The input 162 of the driver 160 is configured to receive an input RF signal (labeled “RF_{IN}”). The input RF signal may come from a mixer (not shown) configured to frequency upconvert a baseband signal or an intermediate frequency (IF) signal into the input RF signal. The input 114 of the Doherty PA 115 is coupled to the output 164 of the driver 160, and the output 116 of the Doherty PA 115 may be coupled to an antenna (e.g., via a transmission line).

In operation, the driver 160 is configured to receive the input RF signal at the input 162 (e.g., from a mixer), and drive the input 114 of the Doherty PA 115 with the RF signal. The Doherty PA 115 is configured to amplify the RF signal, and output the amplified RF signal (labeled “RF_{OUT}”) at the output 116 for transmission (e.g., via the antenna). The Doherty PA 115 may be used, for example, to provide efficient power amplification of an RF signal having a high peak-to-average power ratio (PAPR). For example, the wireless device may use a high-order modulation scheme for high data throughput, which may produce an RF signal having a high PAPR.

In the example shown in FIG. 1, the Doherty PA 115 includes an input circuit 140, a main amplifier 120, an auxiliary amplifier 130, and an output circuit 150. The main amplifier 120 may also be referred to as a carrier amplifier or another term, and the auxiliary amplifier 130 may also referred to as a peaking amplifier or another term. The input circuit 140 has an input 142 coupled to the input 114 of the Doherty PA 115, a first output 144, and a second output 146. The main amplifier 120 has an input 122 coupled to the first output 144 of the input circuit 140, and an output 124. The auxiliary amplifier 130 has an input 132 coupled to the second output 146 of the input circuit 140, and an output 134. The output circuit 150 has a first input 152 coupled to the output 124 of the main amplifier 120, a second input 154 coupled to the output 134 of the auxiliary amplifier 130, and an output 156 coupled to the output 116 of the Doherty PA 115.

The input circuit 140 is configured to split the power of the RF signal received at the input 142 between the first output 144 and the second output 146. In other words, the input circuit 140 is configured to split the RF signal at the input 142 into a first RF signal and a second RF signal, output the first RF signal at the first output 144, and output the second RF signal at the second output 146.

The input circuit 140 may also be configured to provide a phase shift between the first output 144 and the second output 146 (i.e., provide a phase shift between the first RF signal and the second RF signal). The phase shift causes the phase of the first RF signal at the input 122 of the main amplifier 120 to be offset from the phase of the second RF signal at the input 132 of the auxiliary amplifier 130 by the phase shift. In certain aspects, the phase shift is approximately equal to 90 degrees, as discussed further below. In these aspects, the second RF signal may lag the first RF signal by 90 degrees. The input circuit 140 may include a transmission line (e.g., a quarter-wavelength transmission line) and/or one or more lumped element networks for performing the phase shift. The input circuit 140 may also provide impedance matching with the output 164 of the driver 160.

The main amplifier 120 is configured to receive the first RF signal from the first output 144 of the input circuit 140 and amplify the first RF signal. The main amplifier 120 may be biased in class AB and may be on (i.e., active) when the main amplifier 120 is provided with a supply voltage. The auxiliary amplifier 130 is configured to receive the second RF signal from the second output 146 of the input circuit 140 (which is phase shifted (e.g., by 90 degrees) with respect to the first RF signal input to the main amplifier 120), and amplify the second RF signal. The auxiliary amplifier 130 may be biased in class C. In certain aspects, the auxiliary amplifier 130 may be configured to turn on when the main amplifier 120 is driven into saturation or close to saturation. A more detailed discussion of the main amplifier 120 and the auxiliary amplifier 130 is provided below.

The output circuit 150 is configured to combine the RF signals from the main amplifier 120 and the auxiliary amplifier 130, and output the combined RF signal (labeled “RF_{OUT}”) at the output 116 for transmission (e.g., via the antenna). The output circuit 150 may also provide impedance inversion for the main amplifier 120 to modulate the load presented to the main amplifier 120, as discussed further below. The output circuit 150 may include a quarter-wavelength transmission line and/or one or more lumped element networks for performing the impedance inversion. The impedance inversion introduces a 90-degree phase shift in the RF signal from the main amplifier 120. A 90-degree phase shift by the input circuit 140 may be used to compensate for the 90-degree phase shift from the impedance inversion so that the RF signals from the main amplifier 120 and the auxiliary amplifier 130 are combined in phase. As discussed above, the phase shift by the input circuit 140 may cause the second RF signal input to the auxiliary amplifier 130 to lag the first RF signal input to the main amplifier 120 by 90 degrees.

The output circuit 150 may also provide impedance matching with the load (e.g., 50 ohms) coupled to the output 116 of the Doherty PA 115. The load may be the load from a transmission line, an antenna, or another type of circuit. The output circuit 150 may include an output impedance matching network for providing the impedance matching.

As discussed above, the main amplifier 120 may be biased in class AB and the auxiliary amplifier 130 may be biased in class C, in which the main amplifier 120 may be on (i.e., active) when the main amplifier 120 is provided with a supply voltage, and the auxiliary amplifier 130 may be on when the main amplifier 120 is driven into saturation or close to saturation.

In operation, when the power level of the input RF signal is low, the auxiliary amplifier 130 is turned off and the main amplifier 120 provides amplification of the input RF signal. As used herein, the power level of the input RF signal is low when the main amplifier 120 is driven below saturation. When the power level of the input RF signal is high enough to drive the main amplifier 120 into saturation or within some range of saturation, the auxiliary amplifier 130 turns on and provides additional amplification of the input RF signal. Thus, when the main amplifier 120 is driven into or close to saturation, both the main amplifier 120 and the auxiliary amplifier 130 contribute to amplification of the input RF signal. The output current from the auxiliary amplifier 130 (which drives the load) causes the impedance inversion of the output circuit 150 to modulate the impedance seen at the output 124 of the main amplifier 120. The impedance seen at the output 124 of the main amplifier 120 is modulated in a manner that maintains high power efficiency as the main amplifier 120 operates in the saturation region.

In this example, the power efficiency of the Doherty PA 115 as a function of input power may have a first efficiency peak corresponding to a back-off power and a second efficiency peak corresponding to a peak power (also referred to as full power) of the Doherty PA 115. The back-off power may be the power at which the main amplifier 120 enters saturation or close to saturation. In certain aspects, the back-off power may be approximately 6 dB below the peak power.

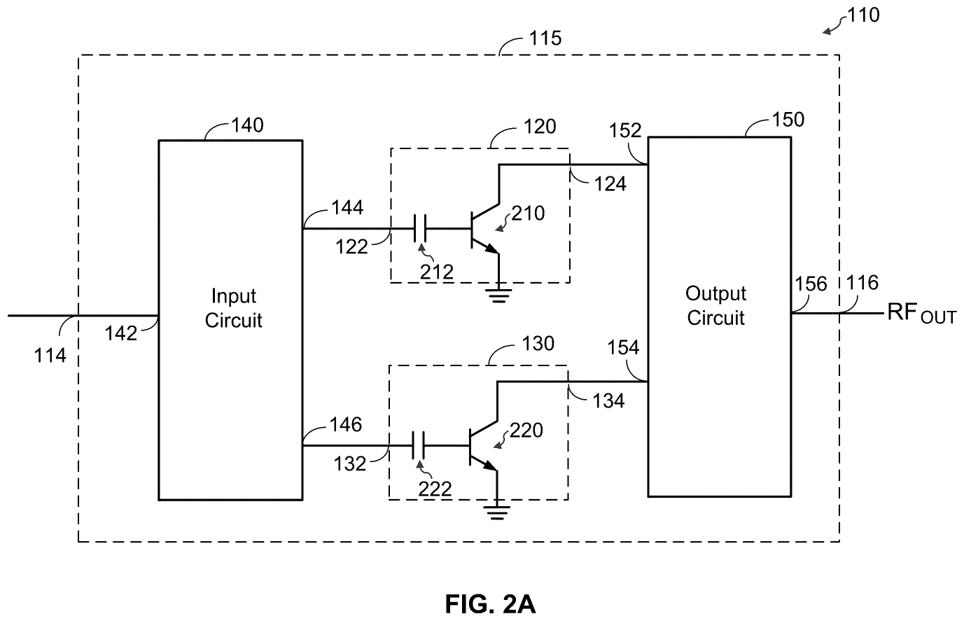

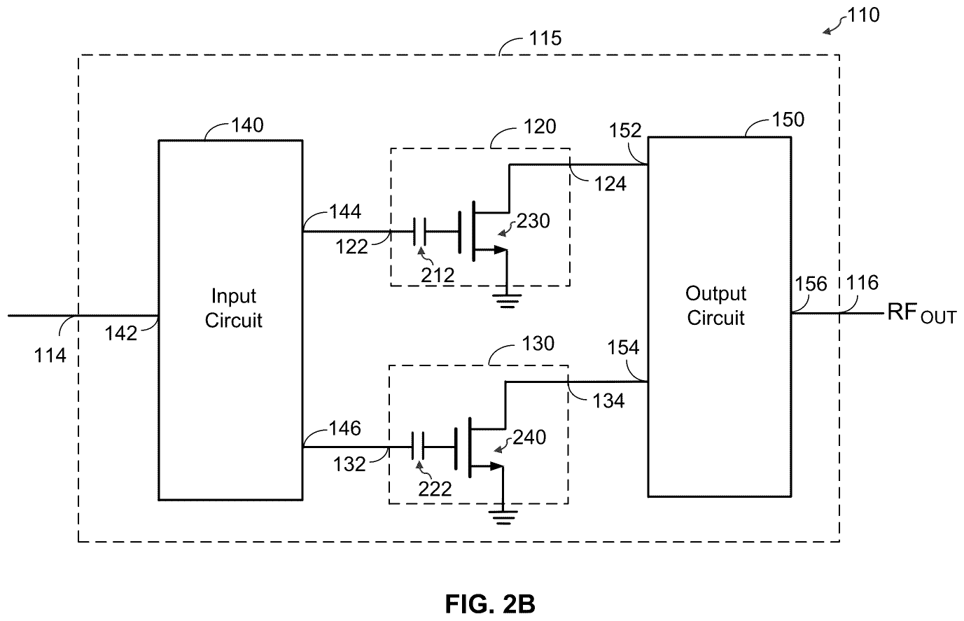

FIG. 2A shows an exemplary implementation of the main amplifier 120 and the auxiliary amplifier 130 according to certain aspects. In this example, the main amplifier 120 includes a first bipolar junction transistor (BJT) 210 and a first coupling capacitor 212. The collector of the first BJT 210 is coupled to the output 124 of the main amplifier 120, and the emitter of the first BJT 210 is coupled to ground (or some reference potential). The first coupling capacitor 212 is coupled between the input 122 of the main amplifier 120 and the base of the first BJT 210. The base of the first BJT 210 may be biased (e.g., in class AB) by a main bias circuit (not shown) coupled between the first coupling capacitor 212 and the base of the first BJT 210.

In this example, the auxiliary amplifier 130 includes a second BJT 220 and a second coupling capacitor 222. The collector of the second BJT 220 is coupled to the output 134 of the auxiliary amplifier 130, and the emitter of the second BJT 220 is coupled to ground (or some reference potential). The second coupling capacitor 222 is coupled between the input 132 of the auxiliary amplifier 130 and the base of the second BJT 220. The base of the second BJT 220 may be biased (e.g., in class C) by an auxiliary bias circuit (not shown) coupled between the second coupling capacitor 222 and the base of the second BJT 220.

It is to be appreciated that each of the first BJT 210 and the second BJT 220 may be implemented with any one of various types of BJTs including, but not limited to, an NPN BJT, a PNP BJT, a heterojunction bipolar transistor (HBT), and the like. As used herein, “N” means N-type and “P” means P-type.

It is also to be appreciated that the main amplifier 120 and the auxiliary amplifier 130 are not limited to BJTs. In this regard, FIG. 2B shows an example in which the main amplifier 120 includes a first field effect transistor (FET) 230 and the auxiliary amplifier 130 includes a second FET 240.

In this example, the drain of the first FET 230 is coupled to the output 124 of the main amplifier 120, the source of the first FET 230 is coupled to ground (or some reference potential), and the first coupling capacitor 212 is coupled between the input 122 of the main amplifier 120 and the gate of the first FET 230. The gate of the first FET 230 may be biased (e.g., in class AB) by a main bias circuit (not shown) coupled between the first coupling capacitor 212 and the gate of the first FET 230.

Also, in this example, the drain of the second FET 240 is coupled to the output 134 of the auxiliary amplifier 130, the source of the second FET 240 is coupled to ground (or some reference potential), and the second coupling capacitor 222 is coupled between the input 132 of the auxiliary amplifier 130 and the gate of the second FET 240. The gate of the second FET 240 may be biased (e.g., in class C) by an auxiliary bias circuit (not shown) coupled between the second coupling capacitor 222 and the gate of the second FET 240.

It is to be appreciated that each of the first FET 230 and the second FET 240 may be implemented with any one of various types of FETs including, but not limited to, an NFET, a PFET, and the like

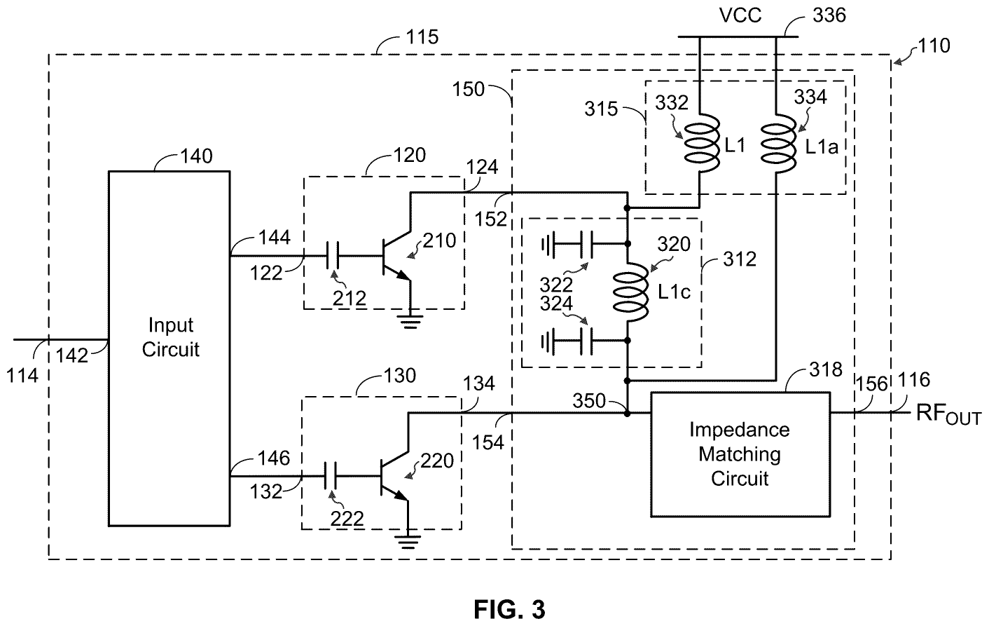

FIG. 3 shows an exemplary implementation of the output circuit 150 according to certain aspects of the present disclosure. In this example, the output circuit 150 includes an impedance inverter 312, an RF choke circuit 315, and an impedance matching circuit 318.

In the example in FIG. 3, the impedance inverter 312 includes a series inductor 320, a first shunt capacitor 322, and a second shunt capacitor 324. The series inductor 320 is coupled between the output 124 of the main amplifier 120 and the output 134 of the auxiliary amplifier 130. The first shunt capacitor 322 is coupled between the output 124 of the main amplifier 120 and ground (or some reference potential). The second shunt capacitor 324 is coupled between the output 134 of the auxiliary amplifier 130 and ground (or some reference potential).

In this example, the series inductor 320 and the shunt capacitors 322 and 324 provide a lumped element network that is approximately equivalent to an impedance inverter implemented with a quarter-wavelength transmission line. In certain aspects, the inductance (labeled L1c) of the inductor 320 may be equal to Z₀/ω₀ where Z₀ is the inverter impedance and do is the angular frequency of the RF signal (i.e., 2π times frequency), and the capacitance of each of the capacitors 322 and 324 may be equal to 1/(Z₀ω₀).

In certain aspects, the lumped element network including the series inductor 320 and the shunt capacitors 322 and 324 may be used to provide the impedance inversion in applications where using the quarter-wavelength transmission line may not be practical. For example, for RF signals in the low GHz range (e.g., 2.44 GHZ), the length of the quarter-wavelength transmission line (e.g., over 3 cm) may be too long to fit in an RF front-end (RFFE) module. In this example, the lumped element network takes up less area compared with the quarter-wavelength transmission line.

The RF choke circuit 315 includes a first choke inductor 332 and a second choke inductor 334. The first choke inductor 332 is coupled between the output 124 of the main amplifier 120 and a supply rail 336, and the second choke inductor 334 is coupled between the output 134 of the auxiliary amplifier 130 and the supply rail 336. The supply rail 336 provides a supply voltage VCC, which is a DC voltage. Because the supply voltage VCC is a DC voltage, the first choke inductor 332 and the second choke inductor 334 act as DC shorts for the supply voltage VCC. As a result, the output 124 of the main amplifier 120 (e.g., the collector of the first BJT 210 or the drain of the first FET 230) is DC biased at VCC through the first choke inductor 332, and the output 134 of the auxiliary amplifier 130 (e.g., the collector of the second BJT 220 or the drain of the second FET 240) is DC biased at VCC through the second choke inductor 334. In certain aspects, one or more decoupling capacitors (not shown) may be coupled between the supply rail 336 and ground.

The first choke inductor 332 also stores energy allowing the output voltage swing of the RF signal at the output 124 of the main amplifier 120 to exceed the supply voltage VCC, and the second choke inductor 334 also stores energy allowing the output voltage swing of the RF signal at the output 134 of the auxiliary amplifier 130 to exceed the supply voltage VCC.

In this example, the impedance matching circuit 318 is coupled between the output 116 of the Doherty PA 115 and an internal node 350. The output 134 of the auxiliary amplifier 130 is coupled to the node 350, and the impedance inverter 312 is coupled between the output 124 of the main amplifier 120 and the node 350.

The impedance matching circuit 318 is configured to transform the impedance seen at the output 116 of the Doherty PA 115 to a target impedance at the node 350. For example, the impedance seen at the output 116 of the Doherty PA 115 may be the impedance (e.g., 50 ohms) of a transmission line, an antenna, or another load coupled to the output 116 of the Doherty PA 115. In this example, the impedance matching circuit 318 may be implemented with an impedance matching network that provides a desired target impedance at the node 350. The impedance matching network 318 may be implemented with a T network, a Pi network, an L network, or another type of network. An exemplary implementation of the impedance matching circuit 318 is discussed further below.

In certain aspects, the target impedance at the node 350 may be chosen based on an impedance value at the node 350 that provides high power efficiency at the back-off power (e.g., 6 dB below the peak power). In these aspects, the impedance value may be determined, for example, by performing a computer simulation or a test that measures power efficiency at the back-off power as a function of the impedance at the node 350, and choosing an impedance value corresponding to a high power efficiency. However, it is to be appreciated that the present disclosure is not limited to this example, and that the target impedance at the node 350 may be determined based on power efficiency at another power level (e.g., power efficiency at the peak power).

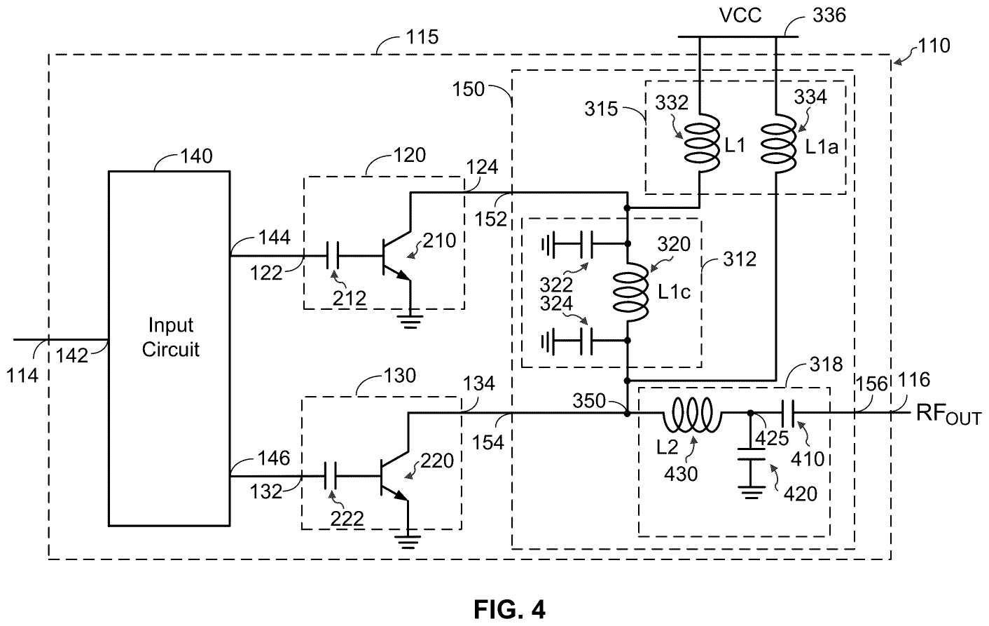

FIG. 4 shows an exemplary implementation of the impedance matching circuit 318 according to certain aspects. In this example, the impedance matching circuit 318 includes an inductor 430, a first capacitor 410, and a second capacitor 420. The first capacitor 410 is coupled between the output 116 of the Doherty PA 115 and an internal node 425, the second capacitor 420 is coupled between the internal node 425 and ground (or some reference potential), and the inductor 430 is coupled between the internal node 425 and the node 350. In this example, the capacitance values of the capacitors 410 and 420 and the inductance value of the inductor 430 may be chosen to achieve the target impedance at the node 350 discussed above.

It is to be appreciated that the impedance matching circuit 318 is not limited to the exemplary impedance matching network shown in FIG. 4, and that the impedance matching circuit 318 may be implemented using other impedance matching network topologies.

In the examples in FIGS. 3 and 4, the inductors 320, 332, and 334 in the output circuit 150 are coupled in a delta network. In certain aspects, the output circuit 150 includes inductors coupled in a star network that combines the RF choke circuit and the impedance inverter, and significantly reduces the sizes of the inductors for greater area efficiency. The above features and other features of the present disclosure are discussed further below.

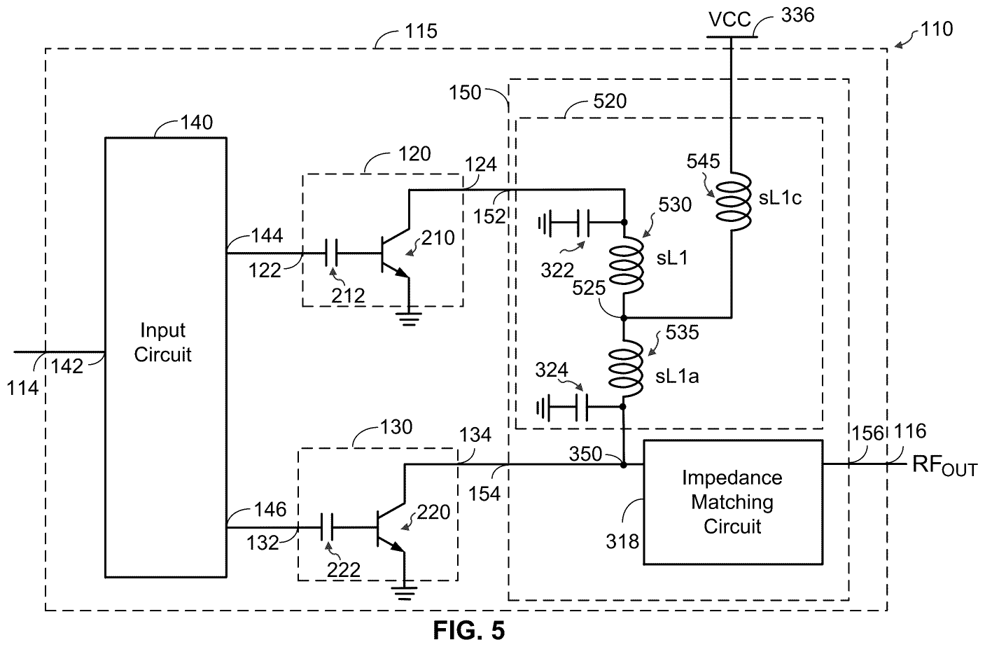

FIG. 5 shows an example in which the output circuit 150 includes a combined circuit 520 that performs functions of the RF choke circuit 315 and the impedance inverter 312 of FIG. 3. The output circuit 150 also includes the impedance matching circuit 318 discussed above.

In the example in FIG. 5, the combined circuit 520 includes a first inductor 530, a second inductor 535, and a third inductor 545 coupled in a star network (also referred to as a Y network), as discussed further below. The combined circuit 520 also includes the first shunt capacitor 322 coupled between the output 124 of the main amplifier 120 and ground (or some reference potential), and the second shunt capacitor 324 coupled between the output 134 of the auxiliary amplifier 130 and ground (or some reference potential).

In this example, the first inductor 530 is coupled between the output 124 of the main amplifier 120 and an internal node 525, the second inductor 535 is coupled between the output 134 of the auxiliary amplifier 130 and the internal node 525, and the third inductor 545 coupled between the supply rail 336 and the internal node 525. The inductors 530, 535, and 545 are coupled in a star network, in which the inductors 530, 535, and 545 are coupled to one another at the node 525.

In this example, the inductors 530, 535, and 545 coupled in the star network provide impedance inverting and RF choke functions. For example, the output 124 of the main amplifier 120 (e.g., the collector of the first BJT 210 or the drain of the first FET 230) is DC biased at VCC through the first inductor 530 and the third inductor 545, and the output 134 of the auxiliary amplifier 130 (e.g., the collector of the second BJT 220 or the drain of the second FET 240) is DC biased at VCC through the second inductor 535 and the third inductor 545. Also, the first inductor 530 and the second inductor 535 provide series inductance between the shunt capacitors 322 and 324 for the impedance inverting function. The third inductor 545 may also contribute to the series inductance.

The inductors 530, 535, and 545 coupled in the star network may significantly reduce inductor sizes compared with the inductors 320, 332, and 334 coupled in the delta network in FIG. 3, as discussed further below. In FIG. 5, the inductances of the inductors 530, 535, and 545 are labeled sL1, sL1a, and sL1c, respectively, and, in FIG. 3, the inductances of the inductors 320, 332, and 334 are labeled L1c, L1, and L1a, respectively. In this example, the star network shown in FIG. 5 may be made approximately equivalent to the delta network shown in FIG. 3 by choosing the inductances sL1, sL1a, and sL1c of the inductors 530, 535, and 545, respectively, based on the following inductance transformations:

$$sL 1 = \frac{L 1 a * L 1 c}{L 1 + L 1 a + L 1 c} \qquad ( Eq . 1 )$$

$$sL 1 a = \frac{L 1 * L 1 c}{L 1 + L 1 a + L 1 c} \qquad ( Eq . 2 )$$

$$sL 1 c = \frac{L 1 * L 1 a}{L 1 + L 1 a + L 1 c} \qquad ( Eq . 3 )$$

where L1c, L1, and L1a are the inductances of the inductors 320, 332, and 334, respectively.

As discussed above, the inductors 530, 535, and 545 coupled in the star network may significantly reduce inductor sizes compared with the inductors 320, 332, and 334 coupled in the delta network in FIG. 3. For example, in one example, the inductances L1 and L1a of the inductors 332 and 334, respectively, may each be equal to 2 nH, and the inductance L1c of the inductor 320 may be equal to 1.3 nH. In this example, the inductances for the inductors 320, 332, and 334 translate into an inductance of 0.5 nH for each of the first and second inductors 530 and 535 (i.e., sL1=sL1a=0.5 nH) in the star network based on equations 1 and 2, and an inductance of 0.75 nH for the third inductor 545 (i.e., sL1c=0.75 nH) in the star network based on equation 3. Thus, in this example, the star network provides a significant reduction in the inductor sizes compared with the delta network, which is desirable for lower cost and area. It is to be appreciated that the present disclosure is not limited to the exemplary inductance values given above, and that the star network also provides significant size reductions over the delta network for other inductance values for L1c, L1, and L1a.

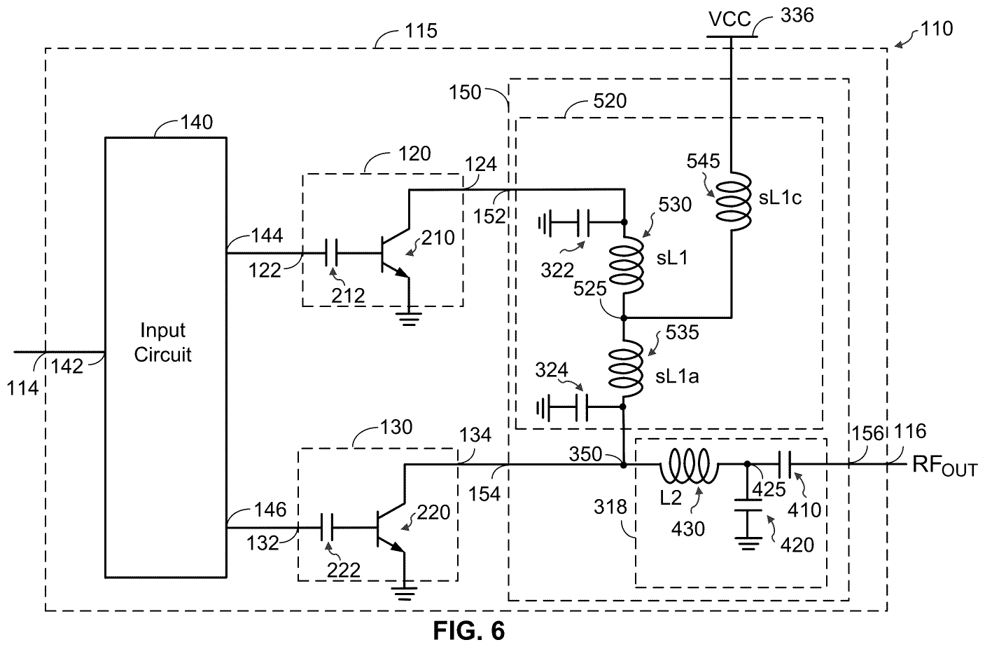

FIG. 6 shows an example in which the impedance matching circuit 318 is implemented with the exemplary implementation shown in FIG. 4. However, as discussed above, the impedance matching circuit 318 is not limited to this example, and the impedance matching circuit 318 may be implemented using other impedance matching network topologies.

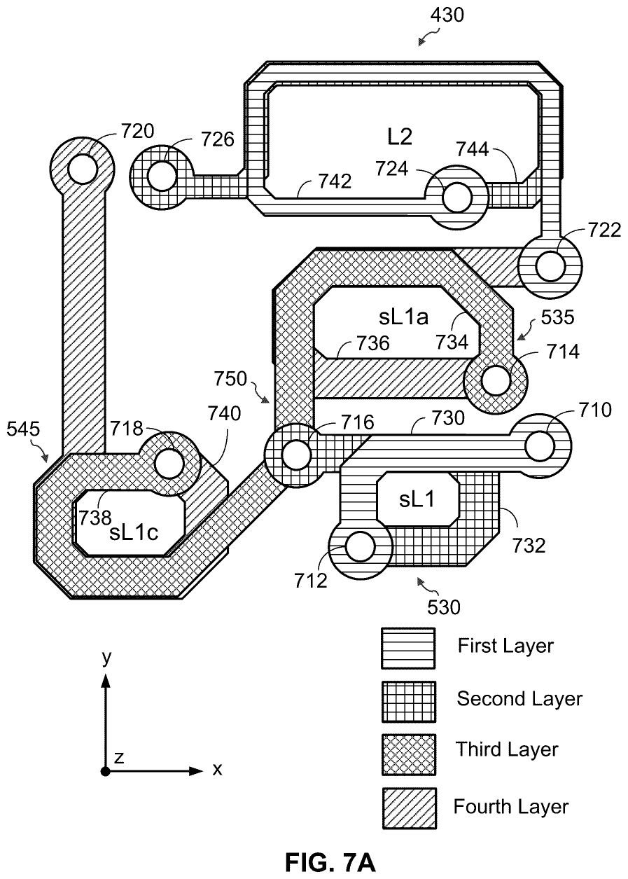

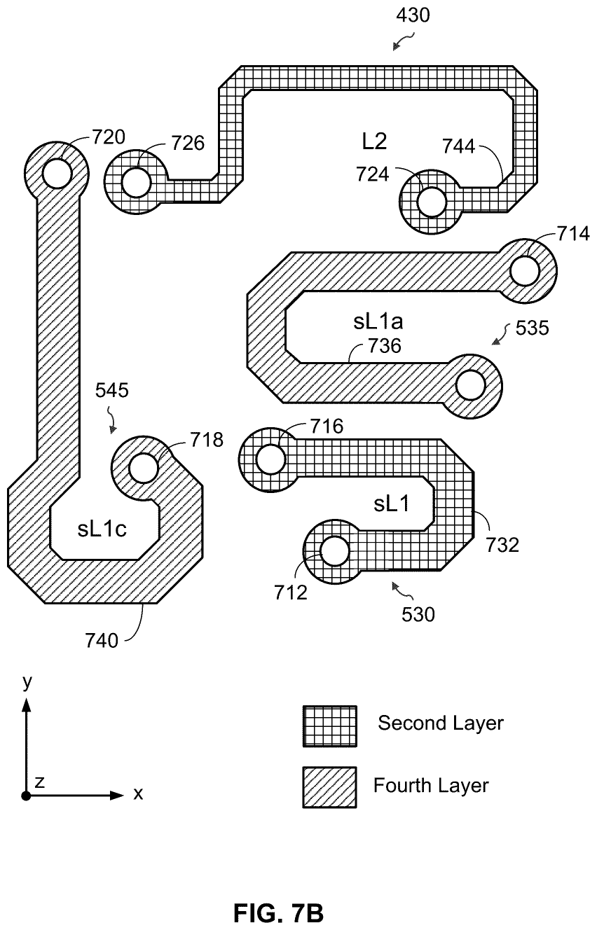

FIG. 7A shows a top view of an exemplary layout of the inductors 530, 535, and 545 according to certain aspects. FIG. 7A also shows an exemplary layout of the inductor 430 for the example where the impedance matching circuit 318 is implemented with the exemplary implementation shown in FIG. 6. It is to be appreciated that the present disclosure is not limited to the exemplary layout shown in FIG. 7A.

In this example, the inductors 530, 535, 545, and 430 are formed in one or more metal layers on and/or embedded in a substrate (e.g., a silicon substrate, a laminate, a low temperature co-fired ceramic, a bismaleimide triazine (BT), a printed circuit board (PCB), etc.). In this example, the main amplifier 120 (e.g., the first BJT 210) and the auxiliary amplifier 130 (e.g., the second BJT 220) may be integrated on a chip that is separate from the substrate. However, it is to be appreciated that the present disclosure is not limited to this example. In other implementations, the inductors 530, 535, 545, and 430 and the amplifiers 120 and 130 may be integrated on the same chip.

In the example in FIG. 7A, the first inductor 530 includes a loop inductor in which a first portion 730 of the first inductor 530 is formed in a first metal layer and a second portion 732 of the first inductor 530 is formed in a second metal layer. The first portion 730 and the second portion 732 of the first inductor 530 may be coupled by a via 712. As used herein, a “via” is a vertical coupling structure for coupling two or more different metal layers. In this example, one end of the first inductor 530 may be coupled to a port through a via 710, in which the port may be coupled to the output 124 of the main amplifier 120 and the first shunt capacitor 322 (shown in FIG. 6).

In the example in FIG. 7A, the second inductor 535 includes a loop inductor in which a first portion 734 of the second inductor 535 is formed in a third metal layer and a second portion 736 of the second inductor 535 is formed in a fourth metal layer. The first portion 734 and the second portion 736 of the second inductor 535 may be coupled by a via 714. In this example, one end of the second inductor 535 may be coupled to a port through a via 722, in which the port may be coupled to the output 134 of the auxiliary amplifier 130 and the second shunt capacitor 324 (shown in FIG. 6).

In the example in FIG. 7A, the third inductor 545 includes a loop inductor in which a first portion 738 of the third inductor 545 is formed in the third metal layer and a second portion 740 of the third inductor 545 is formed in the fourth metal layer. The first portion 738 and the second portion 740 of the third inductor 545 may be coupled by a via 718. In this example, one end of the third inductor 545 may be coupled to a port through a via 720, in which the port may be coupled to the supply rail 336 (shown in FIG. 6).

In the example in FIG. 7A, the first portion 734 of the second inductor 535 and the first portion 738 of the third inductor 545 are coupled by a signal path 750 in the third metal layer, in which the signal path 750 is contiguous with the first portion 734 of the second inductor 535 and the first portion 738 of the third inductor 545 in the third metal layer. Thus, in this example, the second inductor 535 and the third inductor 545 are coupled through the signal path 750. Also, in the example in FIG. 7A, the first inductor 530 is coupled to the signal path 750 through a via 716 between the second inductor 535 and the third inductor 545.

In the example in FIG. 7A, the inductor 430 includes a loop inductor in which a first portion 742 of the inductor 430 is formed in the first metal layer and a second portion 744 of the inductor 430 is formed in the second metal layer. The first portion 742 and the second portion 744 of the inductor 430 may be coupled by a via 724. In this example, one end of the inductor 430 may be coupled to the via 722, which may be coupled to the output 134 of the auxiliary amplifier 130. The other end of the inductor 430 may be coupled to a port through a via 726, in which the port may be coupled to the capacitors 410 and 420 (shown in FIG. 6) in the impedance matching circuit 318.

FIG. 7B shows the exemplary layout of FIG. 7A with the first metal layer and the third metal layer are omitted in order to show structures in the second metal layer and the fourth metal layer obscured by the first metal layer and the third metal layer in FIG. 7A.

It is to be appreciated that the inductors 530, 535, 545, and 430 are not limited to the example shown in FIGS. 7A and 7B. For example, each of the inductors 530, 535, 545, and 430 may include a different number of turns than shown in the example in FIGS. 7A and 7B in some implementations.

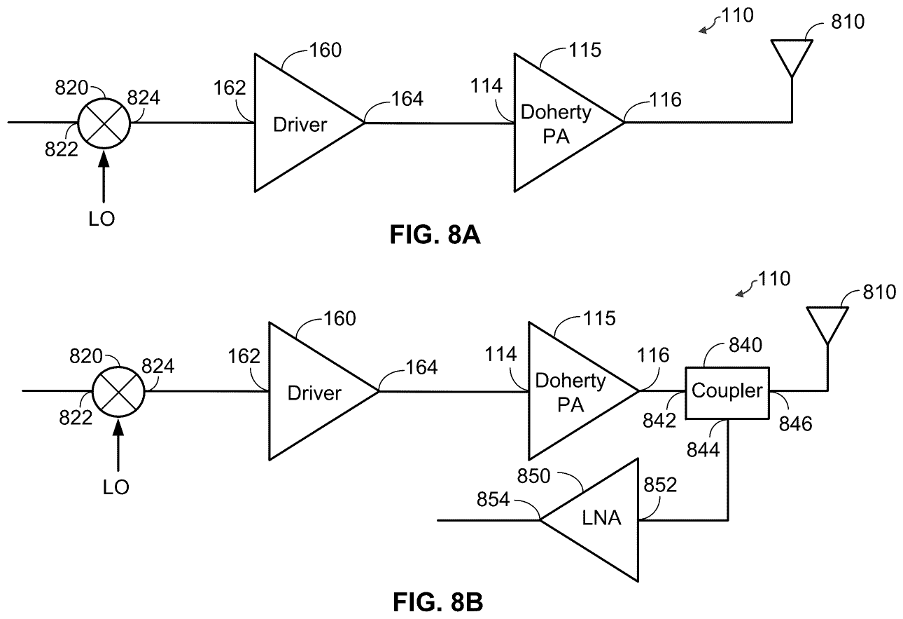

FIG. 8A shows an example of a mixer 820 coupled to the input 162 of the driver 160 and an antenna 810 coupled to the output 116 of the Doherty PA 115. In this example, the mixer 820 has an input 822 configured to receive a baseband signal or an IF signal, and an output 824 coupled to the input 162 of the driver 160. The mixer 820 is configured to mix the baseband signal or the IF signal with a local oscillator signal (labeled “LO”) to frequency upconvert the baseband signal or the IF signal into a RF signal, and output the RF signal at the output 824. The RF signal may correspond to the input RF signal discussed above with reference to FIG. 1.

In this example, the Doherty PA 115 is configured to output the amplifier RF signal to the antenna 810 for transmission. It is to be appreciated that the system 110 may include one or more components (not shown) in the signal path between output 116 of the Doherty PA 115 and the antenna 810 in some implementations.

FIG. 8B shows an example in which the system 110 also includes a low-noise amplifier (LNA) 850 and a coupler 840 according to certain aspects. The LNA 850 has an input 852 and an output 854. The coupler 840 is configured to couple the output 116 of the Doherty PA 115 and the input 852 of the LNA 850 to the antenna 810. This allows the antenna 810 to both transmit and receive RF signals. The coupler 840 may include a diplexer, a duplexer, one or more switches, etc.

In this example, the coupler 840 has a first port 842 coupled to the output 116 of the Doherty PA 115, a second port 844 coupled to the input 852 of the LNA 850, and a third port 846 coupled to the antenna 810. For transmission, the coupler 840 is configured to receive an RF signal from the Doherty PA 115 at the first port 842 and route the RF signal to the third port 846 for transmission via the antenna 810. For reception, the coupler 840 is configured to receive an RF signal from the antenna 810 at the third port 846 and route the RF signal to the input 852 of the LNA 850 via the second port 844. The LNA 850 is configured to amplify the received RF signal, and output the amplified RF signal at the output 854. The output 854 of the LNA 850 may be coupled to a mixer (not shown) configured to frequency downconvert the RF signal into a baseband signal or an IF signal.

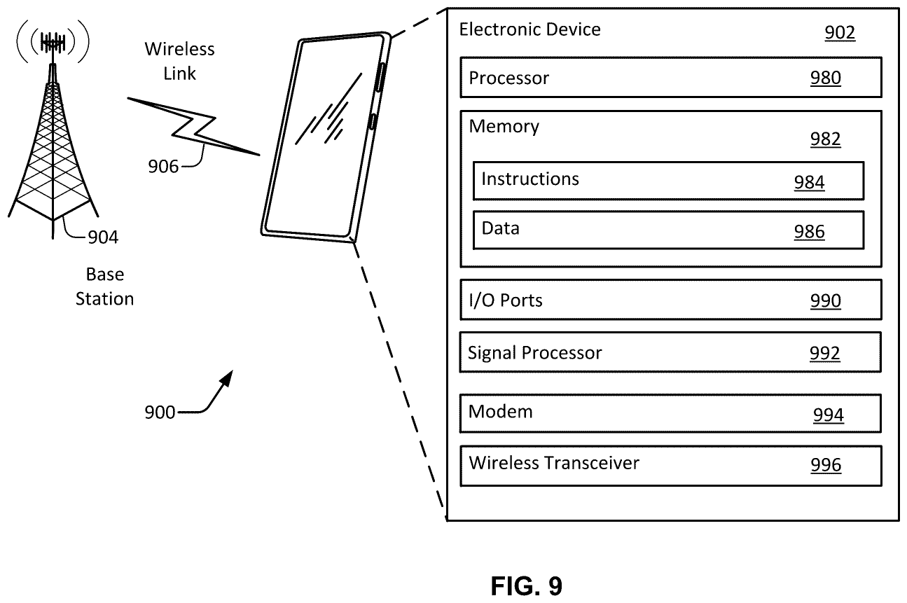

FIG. 9 is a diagram of an environment 900 that includes a wireless device 902 and a base station 904. In the environment 900, the wireless device 902 communicates with the base station 904 via a wireless link 906. As shown, the wireless device 902 is depicted as a smart phone. However, it is to be understood that the wireless device 902 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 904 communicates with the wireless device 902 via the wireless link 906, which may be implemented as any suitable type of wireless link. Although depicted as a base station tower of a cellular radio network, the base station 904 may represent or be implemented as another device, such as a satellite, a terrestrial broadcast tower, an access point, a peer-to-peer device, a mesh network node, and so forth. The wireless link 906 may include a downlink of data and/or control information communicated from the base station 904 to the wireless device 902 and an uplink of other data and/or control information communicated from the wireless device 902 to the base station 904. The wireless link 906 may be implemented using any suitable communication protocol or standard, such as 3rd Generation Partnership Project Long-Term Evolution (3GPP LTE, 3GPP NR 5G), IEEE 902.77, IEEE 902.77, Bluetooth™, and so forth.

The wireless device 902 includes a processor 980 and a memory 982. The memory 982 may be or form a portion of a computer readable storage medium. The processor 980 may include any type of processor, such as an application processor or a multi-core processor, that is configured to execute processor-executable instructions stored in the memory 982. The memory 982 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 982 may store instructions 984, data 986, and other information of the wireless device 902.

The wireless device 902 may also include input/output (I/O) ports 990. The I/O ports 990 enable data exchanges or interaction with other devices, networks, or users or between components of the wireless device 902.

The wireless device 902 may further include a signal processor (SP) 992 (e.g., such as a digital signal processor (DSP)). The signal processor 992 may function similar to the processor 980 and may be capable of executing instructions and/or processing information in conjunction with the memory 982.

For communication purposes, the wireless device 902 also includes a modem 994, a wireless transceiver 996, and one or more antennas (e.g., the antenna 810). The wireless transceiver 996 may include the Doherty PA 115, the mixer 820, the LNA 850, and/or the driver 160 discussed above. The wireless transceiver 996 provides connectivity to respective networks (e.g., the base station 904) and other wireless devices connected therewith using RF signals. The wireless transceiver 996 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:
1. A Doherty power amplifier (PA), comprising:
   a main amplifier;
   an auxiliary amplifier;
   a first inductor coupled between an output of the main amplifier and a first node;
   a second inductor coupled between an output of the auxiliary amplifier and the first node;
   a third inductor coupled between a supply rail and the first node;
   a first capacitor coupled between the output of the main amplifier and a ground;
   a second capacitor coupled between the output of the auxiliary amplifier and the ground; and
   an impedance matching circuit coupled between the output of the auxiliary amplifier and an output of the Doherty PA.
2. The Doherty PA of clause 1, wherein the first inductor comprises a first loop inductor and the second inductor comprises a second loop inductor.
3. The Doherty PA of clause 2, wherein the third inductor comprises a third loop inductor.
4. The Doherty PA of any one of clauses 1 to 3, further comprising an input circuit having an input configured to receive an input radio frequency (RF) signal, a first output coupled to an input of the main amplifier, and a second output coupled to an input of the auxiliary amplifier, wherein the input circuit is configured to split the input RF signal into a first RF signal and a second RF signal, output the first RF signal at the first output, and output the second RF signal at the second output.
5. The Doherty PA of clause 4, wherein the input circuit is configured to provide a phase shift between the first RF signal and the second RF signal.
6. The Doherty PA of clause 5, wherein the phase shift is approximately equal to 90 degrees.
7. The Doherty PA of any one of clauses 4 to 6, wherein the main amplifier comprises:
   a first bipolar junction transistor (BJT), wherein a collector of the first BJT is coupled to the output of the main amplifier, and an emitter of the first BJT is coupled to a ground; and
   a first coupling capacitor coupled between the input of the main amplifier and a base of the first BJT.
8. The Doherty PA of clause 7, wherein the auxiliary amplifier comprises:
   a second BJT, wherein a collector of the second BJT is coupled to the output of the auxiliary amplifier, and an emitter of the second BJT is coupled to the ground; and
   a second coupling capacitor coupled between the input of the auxiliary amplifier and a base of the second BJT.
9. The Doherty PA of any one of clauses 4 to 6, wherein the main amplifier comprises:
   a first field effect transistor (FET), wherein a drain of the first FET is coupled to the output of the main amplifier, and a source of the first FET is coupled to a ground; and
   a first coupling capacitor coupled between the input of the main amplifier and a gate of the first FET.
10. The Doherty PA of clause 9, wherein the auxiliary amplifier comprises:
   a second FET, wherein a drain of the second FET is coupled to the output of the auxiliary amplifier, and a source of the second FET is coupled to the ground; and
   a second coupling capacitor coupled between the input of the auxiliary amplifier and a gate of the second FET.
11. The Doherty PA of any one of clause 1 to 10, wherein the impedance matching circuit comprises:
   a fourth inductor coupled between the output of the auxiliary amplifier and a second node;
   a third capacitor coupled between the second node and a ground; and
   a fourth capacitor coupled between the second node and the output of the Doherty PA.
12. A system for wireless communications, comprising:
   a Doherty power amplifier (PA), comprising:
   a main amplifier;
   an auxiliary amplifier;
   a first inductor coupled between an output of the main amplifier and a first node;
   a second inductor coupled between an output of the auxiliary amplifier and the first node;
   a third inductor coupled between a supply rail and the first node;
a first capacitor coupled between the output of the main amplifier and a ground;
a second capacitor coupled between the output of the auxiliary amplifier and the ground;
and
   an impedance matching circuit coupled between the output of the auxiliary amplifier and an output of the Doherty PA; and
   an antenna coupled to the output of the Doherty PA.
13. The system of clause 12, further comprising a low-noise amplifier (LNA) having an input coupled to the antenna.
14. The system of clause 12 or 13, wherein the Doherty PA further comprises an input circuit having an input configured to receive an input radio frequency (RF) signal, a first output coupled to an input of the main amplifier, and a second output coupled to an input of the auxiliary amplifier, wherein the input circuit is configured to split the input RF signal into a first RF signal and a second RF signal, output the first RF signal at the first output, and output the second RF signal at the second output.
15. The system of clause 14, wherein the input circuit is configured to provide a phase shift between the first RF signal and the second RF signal.
16. The system of clause 15, wherein the phase shift is approximately equal to 90 degrees.
17. The system of any one of clauses 14 to 16, further comprising a mixer coupled to the input of the input circuit.
18. The system of any one of clauses 14 to 17, wherein the main amplifier comprises:
   a first bipolar junction transistor (BJT), wherein a collector of the first BJT is coupled to the output of the main amplifier, and an emitter of the first BJT is coupled to a ground; and
   a first coupling capacitor coupled between the input of the main amplifier and a base of the first BJT.
19. The system of clause 18, wherein the auxiliary amplifier comprises:
   a second BJT, wherein a collector of the second BJT is coupled to the output of the auxiliary amplifier, and an emitter of the second BJT is coupled to the ground; and
   a second coupling capacitor coupled between the input of the auxiliary amplifier and a base of the second BJT.
20. The system of any one of clauses 14 to 17, wherein the main amplifier comprises:
   a first field effect transistor (FET), wherein a drain of the first FET is coupled to the output of the main amplifier, and a source of the first FET is coupled to a ground; and
   a first coupling capacitor coupled between the input of the main amplifier and a gate of the first FET.
21. The system of clause 20, wherein the auxiliary amplifier comprises:
   a second FET, wherein a drain of the second FET is coupled to the output of the auxiliary amplifier, and a source of the second FET is coupled to the ground; and
   a second coupling capacitor coupled between the input of the auxiliary amplifier and a gate of the second FET.
22. The system of any one of clauses 12 to 21, wherein the impedance matching circuit comprises:
   a fourth inductor coupled between the output of the auxiliary amplifier and a second node;
   a third capacitor coupled between the second node and a ground; and
   a fourth capacitor coupled between the second node and the output of the Doherty PA.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A Doherty power amplifier (PA), comprising:
a main amplifier;
an auxiliary amplifier;
a first inductor coupled between an output of the main amplifier and a first node;
a second inductor coupled between an output of the auxiliary amplifier and the first node;
a third inductor coupled between a supply rail and the first node;
a first capacitor coupled between the output of the main amplifier and a ground;
a second capacitor coupled between the output of the auxiliary amplifier and the ground; and
an impedance matching circuit coupled between the output of the auxiliary amplifier and an output of the Doherty PA.

2. The Doherty PA of claim 1, wherein the first inductor comprises a first loop inductor and the second inductor comprises a second loop inductor.

3. The Doherty PA of claim 2, wherein the third inductor comprises a third loop inductor.

4. The Doherty PA of claim 1, further comprising an input circuit having an input configured to receive an input radio frequency (RF) signal, a first output coupled to an input of the main amplifier, and a second output coupled to an input of the auxiliary amplifier, wherein the input circuit is configured to split the input RF signal into a first RF signal and a second RF signal, output the first RF signal at the first output, and output the second RF signal at the second output.

5. The Doherty PA of claim 4, wherein the input circuit is configured to provide a phase shift between the first RF signal and the second RF signal.

6. The Doherty PA of claim 5, wherein the phase shift is approximately equal to 90 degrees.

7. The Doherty PA of claim 4, wherein the main amplifier comprises:
a first bipolar junction transistor (BJT), wherein a collector of the first BJT is coupled to the output of the main amplifier, and an emitter of the first BJT is coupled to a ground; and
a first coupling capacitor coupled between the input of the main amplifier and a base of the first BJT.

8. The Doherty PA of claim 7, wherein the auxiliary amplifier comprises:
a second BJT, wherein a collector of the second BJT is coupled to the output of the auxiliary amplifier, and an emitter of the second BJT is coupled to the ground; and
a second coupling capacitor coupled between the input of the auxiliary amplifier and a base of the second BJT.

9. The Doherty PA of claim 4, wherein the main amplifier comprises:
a first field effect transistor (FET), wherein a drain of the first FET is coupled to the output of the main amplifier, and a source of the first FET is coupled to a ground; and
a first coupling capacitor coupled between the input of the main amplifier and a gate of the first FET.

10. The Doherty PA of claim 9, wherein the auxiliary amplifier comprises:
a second FET, wherein a drain of the second FET is coupled to the output of the auxiliary amplifier, and a source of the second FET is coupled to the ground; and
a second coupling capacitor coupled between the input of the auxiliary amplifier and a gate of the second FET.

11. The Doherty PA of claim 1, wherein the impedance matching circuit comprises:
a fourth inductor coupled between the output of the auxiliary amplifier and a second node;
a third capacitor coupled between the second node and a ground; and
a fourth capacitor coupled between the second node and the output of the Doherty PA.

12. A system for wireless communications, comprising:
a Doherty power amplifier (PA), comprising:
a main amplifier;
an auxiliary amplifier;
a first inductor coupled between an output of the main amplifier and a first node;
a second inductor coupled between an output of the auxiliary amplifier and the first node;
a third inductor coupled between a supply rail and the first node;
a first capacitor coupled between the output of the main amplifier and a ground;
a second capacitor coupled between the output of the auxiliary amplifier and the ground; and
an impedance matching circuit coupled between the output of the auxiliary amplifier and an output of the Doherty PA; and
an antenna coupled to the output of the Doherty PA.

13. The system of claim 12, further comprising a low-noise amplifier (LNA) having an input coupled to the antenna.

14. The system of claim 12, wherein the Doherty PA further comprises an input circuit having an input configured to receive an input radio frequency (RF) signal, a first output coupled to an input of the main amplifier, and a second output coupled to an input of the auxiliary amplifier, wherein the input circuit is configured to split the input RF signal into a first RF signal and a second RF signal, output the first RF signal at the first output, and output the second RF signal at the second output.

15. The system of claim 14, wherein the input circuit is configured to provide a phase shift between the first RF signal and the second RF signal.

16. The system of claim 15, wherein the phase shift is approximately equal to 90 degrees.

17. The system of claim 14, further comprising a mixer coupled to the input of the input circuit.

18. The system of claim 14, wherein the main amplifier comprises:
a first bipolar junction transistor (BJT), wherein a collector of the first BJT is coupled to the output of the main amplifier, and an emitter of the first BJT is coupled to a ground; and
a first coupling capacitor coupled between the input of the main amplifier and a base of the first BJT.

19. The system of claim 18, wherein the auxiliary amplifier comprises:
a second BJT, wherein a collector of the second BJT is coupled to the output of the auxiliary amplifier, and an emitter of the second BJT is coupled to the ground; and
a second coupling capacitor coupled between the input of the auxiliary amplifier and a base of the second BJT.

20. The system of claim 12, wherein the impedance matching circuit comprises:
a fourth inductor coupled between the output of the auxiliary amplifier and a second node;
a third capacitor coupled between the second node and a ground; and
a fourth capacitor coupled between the second node and the output of the Doherty PA.
